(19) United States
(12) Patent Application Publication
(10) Pub. No.: US 2025/0008657 A1
(43) Pub. Date: Jan. 2, 2025

(54) Display Panel and Display Device

(71) Applicants: Mianyang HKC Optoelectronics Technology Co., Ltd., Mianyang (CN); HKC CORPORATION LIMITED, Shenzhen (CN)

(72) Inventors: Rong TANG, Mianyang (CN); Lidan YE, Mianyang (CN)

(73) Assignee: Mianyang HKC Optoelectronics Technology Co., Ltd., Mianyang (CN)

(21) Appl. No.: 18/759,969

(22) Filed: Jun. 30, 2024

(30) Foreign Application Priority Data
Jun. 30, 2023 (CN) 202310799157.4

(51) Int. Cl. H05K 1/14; H05K 1/02

(52) U.S. Cl. CPC H05K 1/142; H05K 1/0296; H05K 2201/10128

(57) ABSTRACT

Disclosed are a display panel and a display device. The display panel includes a driver chip, a signal line, a line and a substrate, in which the line connects the driver chip and the signal line, and the line includes a first connecting line and a second connecting line connected to each other, and the substrate includes a hard substrate and a flexible substrate, in which the first connecting line is provided on the hard substrate, and the second connecting line is formed on the flexible substrate when the flexible substrate is stretched; the second connecting line is connected to the first connecting line when the flexible substrate is contracted.

### CROSS-REFERENCE OF RELATED APPLICATIONS

The present disclosure claims all benefits of the Chinese patent application No. 202310799157.4 filed on Jun. 30, 2023 before the China National Intellectual Property Administration of the People's Republic of China, entitled “Display Panel and Display Device”, which is incorporated herein by reference in its entirety.

### FIELD

The present disclosure relates to the field of display technology, particularly to a display panel and a display device.

### BACKGROUND

In a display panel, in general, scanning lines, signal lines and common electrodes work together to display different pictures, in which the signal lines control gray scale voltage data required for display. Generally, each pixel is composed of three sub-pixels, and gray scale corresponding to each sub-pixel is controlled by one signal line. The voltage required for each signal line to complete the display is generally output by a driver chip to a panel in a point-to-point manner. Because a width of the driver chip is smaller than a width of all signal lines in a corresponding area on the panel, lines connecting the signal lines and the driver chip will generally form a sector area.

With the development of display industry, consumers demand higher and higher display resolution, which often needs to carry a plurality of integrated driver chips to meet display load requirements; due to different positions of signal lines on corresponding panels of different chips, lengths of fan-out lines in each sector area are different, and fan-out lines located outside in each sector area are greater than fan-out lines located inside. Length difference between the fan-out lines will lead to resistance difference between the fan-out lines, which causes different degrees of signal attenuation of data signal voltage output from the driver chip, and finally renders uneven image display of the display panel.

### SUMMARY

The disclosure provides a display panel and a display device to solve a problem that data signal voltage output from the driver chip has different degrees of signal attenuation, resulting in uneven image display of the display panel.

In a first aspect, the present disclosure provides a display panel comprising a driver chip and a signal line, comprising:
a line connecting the driver chip and the signal line, comprising a first connecting line and a second connecting line connected to each other; and
a hard substrate and a flexible substrate, wherein the first connecting line is provided on the hard substrate, the second connecting line is formed on the flexible substrate when the flexible substrate is stretched, and the second connecting line is connected to the first connecting line when the flexible substrate is contracted.

In some embodiments, the second connecting line is connected to an end of the first connecting line.

In some embodiments, the first connecting line comprises a first connecting section and a second connecting section, one end of the second connecting line is connected to one end of the first connecting section, and the other end of the second connecting line is connected to the one end of the second connecting section, the other end of the first connecting section is connected to the signal line, and the other end of the second connecting section is connected to the driver chip.

In some embodiments, the first connecting line and the second connecting line are adhesively connected by conductive fluid.

In some embodiments, the flexible substrate can be stretched transversely or longitudinally on a horizontal plane.

In some embodiments, the flexible substrate can be stretched transversely and longitudinally on a horizontal plane.

In some embodiments, a thickness of the second connecting line is smaller than a thickness of the first connecting line when the flexible substrate is stretched; a thickness of the second connecting line is the same as a thickness of the first connecting line when the flexible substrate is contracted.

In some embodiments, the hard substrate is provided with an accommodating groove, and the flexible substrate is embedded in the accommodating groove.

In some embodiments, a depth of the accommodating groove is the same as a thickness of the flexible substrate.

In some embodiments, the flexible substrate comprises a flexible printed surface, the second connecting line is provided on the flexible printed surface, and a thickness direction of the hard substrate is parallel to the flexible printed surface.

In some embodiments, the hard substrate comprises a hard printed surface, the first connecting line is provided on the hard printed surface, the flexible substrate further comprises a first side surface and a second side surface which are both parallel to the hard printed surface and perpendicular to the flexible printed surface, and both ends of the second connecting line are provided on the first side surface.

In some embodiments, the first side surface is provided above the second side surface.

In some embodiments, the hard substrate comprises a hard printed surface, the first connecting line is provided on the hard printed surface, the flexible substrate further comprises a first side surface and a second side surface which are both parallel to the hard printed surface and perpendicular to the flexible printed surface, and two ends of the second connecting line are provided on the first side surface and the second side surface respectively.

In some embodiments, there is a sector area between the signal line and the driver chip, the line is arranged in the sector area, and the sector area includes two outer areas and two inner areas between the two outer areas; a length of the first connecting line in the outer area is greater than a length of the first connecting line in the inner area, and a length of the second connecting line in the outer area is smaller than a length of the second connecting line in the inner area.

In a second aspect, the present disclosure provides a display device comprising a display panel comprising a driver chip and a signal line, the display panel further comprising:
a line connecting the driver chip and the signal line, comprising a first connecting line and a second connecting line connected to each other; and
a hard substrate and a flexible substrate, wherein the first connecting line is provided on the hard substrate, the second connecting line is formed on the flexible substrate when the flexible substrate is stretched, and the second connecting line is connected to the first connecting line when the flexible substrate is contracted.

In the display panel provided by some embodiments of the present disclosure, when the flexible substrate is stretched, the second connecting line is wound on the flexible substrate, and when the flexible substrate is contracted, the second connecting line on the flexible substrate will be contracted and become thinner, thus forming a superfine line on the flexible substrate, increasing the length of the line in the same area, and then the second connecting line is connected to the first connecting line, so as to adjust a plurality of lines into lines with the same length, ensuring consistent impedance of a plurality of the lines and uniformity of display. In addition, by forming the second connecting line on the flexible substrate when the flexible substrate is stretched, a superfine line is obtained after the flexible substrate is contracted; compared with a process of directly preparing a superfine line, the disclosure reduces manufacturing difficulty and precision of a superfine line.

### BRIEF DESCRIPTION OF DRAWINGS

Accompanying drawings herein, which are incorporated in the description and constitute a part of the description, illustrate embodiments according to the disclosure and explain the principle of the disclosure together with the description.

In order to more clearly illustrate technical solutions of embodiments of the disclosure, drawings that need to be used in description of the embodiments are briefly introduced below, and it will be apparent to those of ordinary skill in the art that other drawings can be obtained based on these drawings without inventive work.

One or more embodiments are illustrated by the corresponding drawings, which do not constitute a limitation of the embodiments. Elements with the same reference numerals in the drawings represent similar elements, and the drawings in the drawings do not constitute a scale limitation unless otherwise specified.

FIG. 1 is an overall structure schematic diagram of a display panel according to an embodiment of the present disclosure;

FIG. 2(a) is a structure schematic diagram of a flexible substrate;

FIG. 2(b) is a structure schematic diagram of the flexible substrate after transverse stretch;

FIG. 2(c) is a structure schematic diagram of arranging a second connecting line in FIG. 2(b);

FIG. 2(d) is a structure schematic diagram of FIG. 2(c) after contraction;

FIG. 2(e) is a structure schematic diagram of FIG. 2(a) after both transverse and longitudinal stretch;

FIG. 2(f) is a structure schematic diagram of arranging the second connecting line in FIG. 2(e);

FIG. 2(g) is a structure schematic diagram of FIG. 2(f) after contraction;

FIG. 3 is a top view of a hard substrate;

FIG. 4 is a side view of a hard substrate; and

FIG. 5 is a schematic diagram of a display device according to an embodiment of the present disclosure.

### DESCRIPTION OF REFERENCE NUMERALS

10. Display panel;
1. Driver chip; 2. Signal line;
3. Line; 31. First connecting line; 311. First connecting section; 312. Second connecting section; 32. Second connecting line;
4. Hard substrate; 41. Accommodating groove; 42. Hard printed surface;
5. Flexible substrate; 51. Flexible printed surface; 52. First side; 53. Second side;
6. Conductive fluid;
7. Sector area; 71. Outer area; 72. Inner area;
11. Display device.

### DETAILED DESCRIPTION OF EMBODIMENTS

In order to make objectives, technical solutions, and advantages of embodiments of the disclosure clearer, the technical solutions in the embodiments of the disclosure will be clearly and fully described below in combination with the accompanying drawings in the embodiments of the disclosure. Obviously, the embodiments to be described are part of embodiments but not all embodiments of the disclosure. Based on the embodiments in the disclosure, all other embodiments obtained by those of ordinary skill in the art without inventive work shall fall within the scope of the disclosure.

Many different embodiments or examples are provided below to realize different structures of the disclosure. In order to simplify the disclosure, components and arrangements of specific examples are described below. Of course, they are only examples and are not intended to limit the disclosure. Furthermore, the present disclosure may repeat reference numerals and/or letters in different examples. The repetition is for simplicity and clarity, and in itself does not indicate the relationship between the various embodiments and/or arrangements discussed.

For the convenience of description, spatial relationship terms can be used herein to describe the relative positional relationship or movement of one element or feature relative to another element or feature as shown in the drawings, such as “inside”, “outside”, “inner”, “outer”, “under”, “below”, “on”, “above”, “front” and “back”. This spatial relationship term is intended to include different orientations of the device in use or operation other than orientations depicted in the drawings. For example, if the device in the drawings has a position turnover, a posture change or a movement state change, these directional indications will change accordingly, for example: Elements described as “under or below other elements or features” will be subsequently oriented as “on or over other elements or features”. Thus, the example term “below” may include both orientations of above and below. The device may be otherwise oriented (rotated by 90 degrees or in other directions), and the spatial relationship description used herein are interpreted accordingly.

### First Embodiment

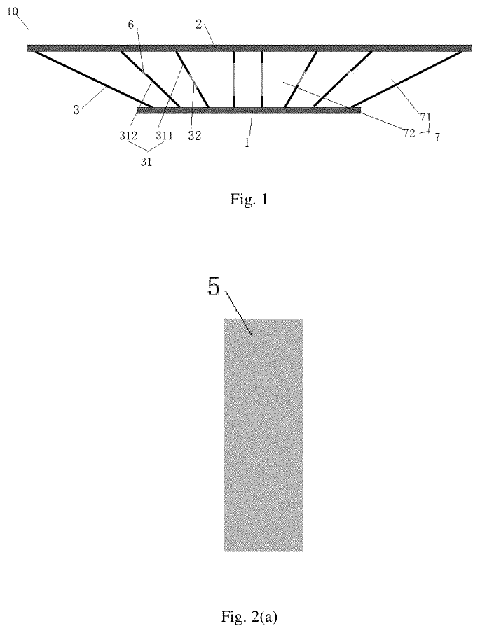

Referring to FIGS. 1 to 3, an embodiment of the present disclosure provides a display panel 10 comprising a driver chip 1 and a signal line 2, comprising:
a line 3 connecting the driver chip 1 and the signal line 2, which comprises a first connecting line 31 and a second connecting line 32 connected to each other; and
a hard substrate 4 and a flexible substrate 5, wherein the first connecting line 31 is disposed on the hard substrate 4; the second connecting line 32 is formed on the flexible substrate 5 when the flexible substrate 5 is stretched; and the second connecting line 32 is connected to the first connecting line 31 when the flexible substrate 5 is contracted.

When the flexible substrate 5 stretched, the second connecting line 32 is wound on the flexible substrate 5, and when the flexible substrate 5 is contracted, the second connecting line 32 on the flexible substrate 5 will be contracted and become thinner, thus forming a superfine line on the flexible substrate 5, increasing the length of the line in the same area, and then the second connecting line 32 is connected to the first connecting line 31, so as to adjust a plurality of lines 3 into lines 3 with the same length, ensuring consistency of impedance of a plurality of the lines 3 and uniformity of display. In addition, by forming the second connecting line 32 on the flexible substrate 5 when the flexible substrate 5 is stretched, a superfine line is obtained after the flexible substrate 5 is contracted; compared with a process of directly preparing a superfine line, the disclosure reduces manufacturing difficulty and precision of a superfine line.

In the field of panel design, since the width of the driver chip 1 is smaller than the width of any signal line 2 in the corresponding area on the panel, the lines 3 connecting the signal line 2 and the driver chip 1 will form a fan-out area, and inconsistent lengths of the lines 3 in the fan-out area will lead to inconsistent impedance of the lines 3, thus affecting the uniformity of display. To solve this problem, the lines 3 with different lengths among a plurality of the lines 3 are wound, so as to adjust the lengths of the lines 3 at different positions to be the same and ensure the same impedance of the lines 3. However, an area occupied by the lines 3 by winding is large, which is difficult to adapt to a development trend of narrow bezel of a display device.

Referring to FIG. 1, there is a sector area 7 between the signal line 2 and the driver chip 1, and the lines 3 are arranged in the sector area 7. The sector area 7 includes two outer areas 71 and an inner area 72 located between the two outer areas 71. The length of the first connecting line 31 in the outer area 71 is greater than that in the inner area 72, and the length of the second connecting line 32 in the outer area 71 is smaller than that in the inner area 72. Therefore, the lengths of the lines 3 in the sector area 7 are the same, and impedance of the lines 3 is the same, thus ensuring the display effect. Of course, the line in the outer area 71 can also only include the first connecting line 31, and both ends of the first connecting line 31 are connected to the signal line 2 and the driver chip 1 respectively. The line 3 does not include the second connecting line 32, so it is not necessary to set the flexible substrate 5 in the region corresponding to the line 3, and it is sufficient to set only the hard substrate 4 in this region, thus simplifying a preparation process. However, the length of the first connecting line 31 in the inner area 72 is smaller than that in the outer area 71, and the length of the second connecting line 32 in the inner area 72 is compensated according to a difference between the length of the first connecting line 31 connected thereto and the length of the first connecting line 31 in the outer area 71, so that the lengths of the lines 3 in the sector area 7 are the same.

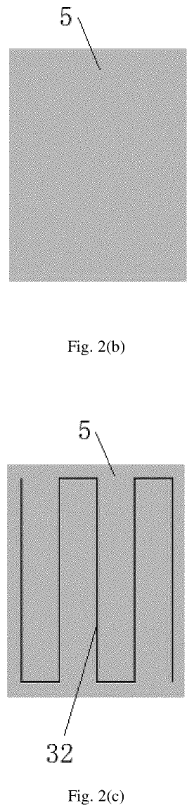

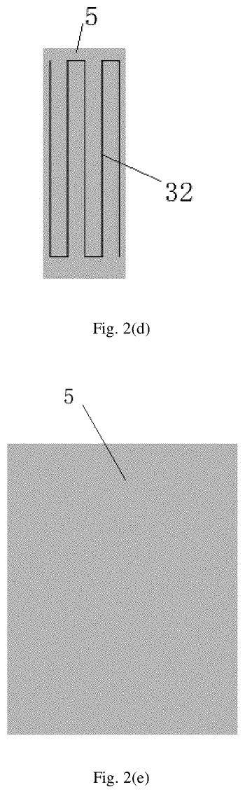

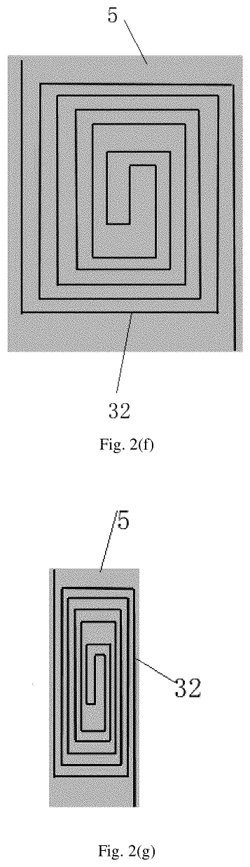

Referring to FIG. 1 and FIG. 2, in this disclosure, wiring and connection of the second connecting line 32 are realized by stretching and contraction the flexible substrate 5, and the length of the second connecting line 32 is increased by winding the line on the flexible substrate 5 when the flexible substrate 5 is stretched, and a cross-sectional area of the second connecting line 32 can be reduced after the flexible substrate 5 is contracted, so that a layout area of the fan-out area will not be increased after the second connecting line 32 is connected. In addition, the winding lengths of the second connecting lines 32 are gradually reduced from the lines 3 in the middle to the lines 3 on both sides, so that the lengths of a plurality of the lines 3 can be adjusted to be the same without changing the occupied area of the lines 3, so as to ensure the same impedance of a plurality of the lines 3 and the display effect.

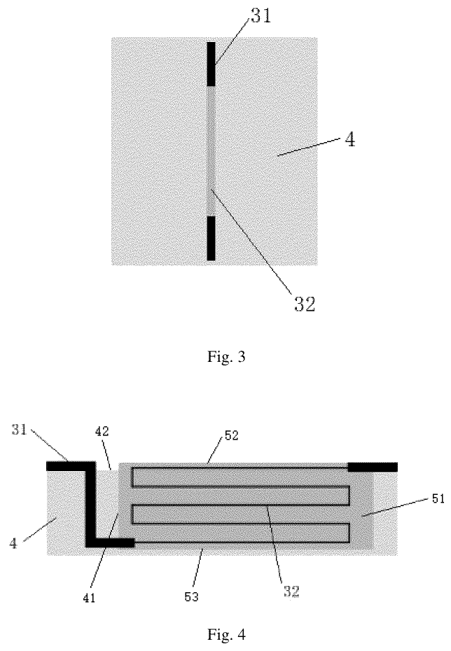

The flexible substrate 5 can be stretched transversely and/or longitudinally in the horizontal plane. When the flexible substrate 5 can be stretched transversely in the horizontal plane, that is, referring to FIG. 3(a) to FIG. 3(d), the flexible substrate 5 can be stretched and contracted in the left-right direction, and the second connecting line 32 is printed on when the flexible substrate 5 is stretched, and the second connecting line 32 forms a superfine winding structure after the flexible substrate 5 is contracted. Of course, the flexible substrate 5 can also be stretched longitudinally in the horizontal plane, that is, the flexible substrate 5 can be stretched and contracted in the upper-lower direction. Optionally, referring to FIG. 2(e) to FIG. 2(g), the flexible substrate 5 can be stretched both transversely and longitudinally in the horizontal plane. When the flexible substrate 5 is stretched, a surface area thereof can be enlarged in equal proportion, so that the winding length on the flexible substrate 5 is greatly increased, and more complicated wiring structures can be wound, and an area of the flexible substrate 5 after contracted can be restored to the minimum, thus realizing a complicated winding and wiring mode. For the line 3 in the middle of a plurality of the lines 3, a length thereof is the shortest among lengths of a plurality of the lines 3, so the length of the second connecting line 32 is the longest. At this time, the flexible substrate 5 which can be stretched both transversely and longitudinally to realize preparation and connection of the second connecting line 32 with the longest length.

Referring to FIG. 1, the second connecting line 32 is connected to an end of the first connecting line 31, and after connecting the second connecting line 32 to the first connecting line 31, the other end of the second connecting line 32 may be connected to the signal line 2 or the driver chip 1. Correspondingly, when the other end of the second connecting line 32 is connected to the signal line 2, the other end of the first connecting line 31 is connected to the driver chip 1. When the other end of the second connecting line 32 is connected to the driver chip 1, the other end of the second connecting line 32 is connected to the signal line 2, thereby electrically connecting the driver chip 1 with the signal line 2 in the display panel 10.

Of course, the second connecting line 32 can also be connected to the middle position of the first connecting line 31, that is, the first connecting line 31 includes a first connecting section 311 and a second connecting section 312, an end of the second connecting line 32 is connected to an end of the first connecting section 311, the other end of the second connecting line 32 is connected to the second connecting section 312, the other end of the first connecting section 311 is connected to the signal line 2, and the other end of the second connecting section 312 is connected to the driver chip 1, so as to realize electrical connection between the driver chip 1 and the signal line 2. However, it is necessary to connect four joints through the above connection method, which has many preparation steps and increases preparation difficulty.

Similarly, the first connecting line 31 can also be connected to the middle position of the second connecting line 32, that is, the second connecting line 32 includes a third connecting section and a fourth connecting section. A specific connection mode thereof is the same as above, which will not be described in this embodiment.

When the flexible substrate 5 is stretched, the thickness of the second connecting line 32 is smaller than that of the first connecting line 31; when the flexible substrate 5 is contracted, the thickness of the second connecting line 32 is the same as that of the first connecting line 31; when the flexible substrate 5 is stretched, the second connecting line 32 is deposited on the flexible substrate 5, and the thickness of the second connecting line 32 on the flexible substrate 5 is smaller than that of the first connecting lines 31 on the hard substrate 4; when the flexible substrate 5 is contracted, the thickness of the second connecting lines 32 on the flexible substrate 5 is increased, so that after the second connecting line 32 is connected to the first connecting lines 31, the thickness of the second connecting line 32 on the flexible substrate 5 is the same as that of the first connecting line 31 on the hard substrate 4.

Since the first connecting line 31 is provided on the hard substrate 4, the second connecting line 32 is provided on the flexible substrate 5, and the hard substrate 4 includes a glass substrate, the first connecting line 31 and the second connecting line 32 are adhesively connected by conductive fluid 6 to ensure stability of the joint between the first connecting line 31 and the second connecting line 32. The first connecting line 31 and the second connecting line 32 are electrically connected by a conductive fluid 6 with adhesiveness which has fluidity before curing, and the conductive fluid 6 can form an adhesive structure after curing, thus ensuring stable connection between the first connecting line 31 and the second connecting line 32. Of course, the flexible substrate 5 and the hard substrate 4 can also be adhesively connected by fluid, thus realizing stable connection between the flexible substrate 5 and the hard substrate 4.

Referring to FIGS. 3 and 4, the hard substrate 4 is provided with an accommodating groove 41, and the flexible substrate 5 is embedded in the accommodating groove 41. Providing the accommodating groove 41 provides a connection position for the flexible substrate 5 on the hard substrate 4, and structure configuration of the accommodating groove 41 can also ensure stability of the flexible substrate 5 after connection.

The depth of the accommodating groove 41 is the same as the thickness of the flexible substrate 5. After the flexible substrate 5 is placed in the accommodating groove 41, the upper surface of the flexible substrate 5 is aligned with the upper surface of the hard substrate 4, which ensures flatness of the surface of the display panel 10 after connection and facilitates the subsequent work. In addition, the second connecting line 32 is provided on the upper surface of the flexible substrate 5, and the first connecting line 31 is provided on the upper surface of the hard substrate 4, so that the first connecting line 31 and the second connecting line 32 are connected at the same height, which facilitates connection between the first connecting line 31 and the second connecting line 32, and can also ensure stability of the first connecting line 31 and the second connecting line 32 after connection and reduce the possibility that the first connecting line 31 and the second connecting line 32 are disconnected at the joint.

The flexible substrate 5 includes a flexible printed surface 51, and the second connecting line 32 is provided on the flexible printed surface 51. The thickness direction of the hard substrate 4 is parallel to that of the flexible printed surface 51. The thickness direction of the hard substrate 4 is parallel to the flexible printed surface 51. At this time, the width or thickness direction of the flexible substrate 5 is parallel to a surface of the hard substrate 4 where the first connecting lines 31 is provided, and the width or thickness of the flexible substrate 5 is smaller than the length of the flexible substrate 5, thereby reducing the space occupied by the flexible substrate 5 on the hard substrate 4.

Alternatively, since the thickness of the flexible substrate 5 is smaller than the width and the length of the flexible substrate 5, when the thickness direction of the hard substrate 4 is parallel to the flexible printed surface 51, the thickness direction of the flexible substrate 5 is parallel to a surface of the hard substrate 4 where the first connecting line 31 is provided, so that the flexible substrate 5 is embedded in the hard substrate 4, which reduces the space occupied by the flexible substrate 5 on the horizontal plane of the hard substrate 4.

Referring to FIG. 3 and FIG. 4, the hard substrate 4 includes a hard printed surface 42, the first connecting line 31 is provided on the hard printed surface 42, the flexible substrate 5 further includes a first side surface 52 and a second side surface 53 which are both parallel to the hard printed surface 42 and perpendicular to the flexible printed surface 51, the first side surface 52 is provided above the second side surface 53, and both ends of the second connecting line 32 are provided on the first side surface 52. The first side surface 52 is parallel to the hard printed surface 42, including that the first side surface 52 and the hard printed surface 42 are located on the same plane, or there is a height difference between the first side surface 52 and the hard printed surface 42. Alternatively, the first side surface 52 of the flexible substrate 5 and the hard printed surface 42 of the hard substrate 4 are located on the same plane, and both ends of the second connecting line 32 are located on the first side surface 52, so that the second connecting line 32 and the first connecting line 31 are located on the same plane, which facilitates connection between the first connecting line 31 and the second connecting line 32, and can ensure stability of the first connecting line 31 and the second connecting line 32 after connection.

Of course, both ends of the second connecting line 32 can also be located on the first side surface 52 and the second side surface 53 respectively, and the end of the second connecting line 32 on the first side 52 can be directly connected. Since the end of the second connecting line 32 on the second side surface 53 is inside the hard substrate 4, the hard substrate 4 needs to be provided with a corresponding slot, and components located on the hard printed surface 42 of the hard substrate 4 are connected to the ends of the second connecting line 32 by injecting a liquid connector into the slot.

In summary, in the display panel 10 provided by the present disclosure, the second connecting line 32 is provided on the stretchable flexible substrate 5: first the flexible substrate 5 is stretched greatly, then wiring deposition of the second connecting line 32 is carried out, and the flexible substrate 5 will be contracted and recovered after the wiring, so that the second connecting line 32 is also contracted and thinned, so as to obtain the superfine second connecting line 32; the overall length of the lines 3 can be increased and the cross-sectional area of the line 3 can be reduced by winding, and a winding degree of the second connecting line 32 gradually decreases from the lines 3 in the middle to the lines 3 on two sides to ensure consistent impedance of the lines 3. The winding mode according to this disclosure will not increase the area occupied by the lines 3, and can ensure consistent impedance of a plurality of the lines 3 without increasing the layout area of the fan-out area.

### Second Embodiment

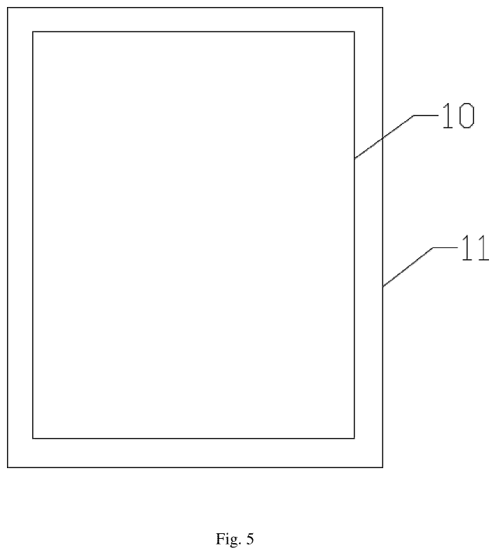

Referring to FIGS. 1-5, an embodiment of the present disclosure also provides a display device 11 including the display panel 10 according to the above embodiment. The technical features of the display panel 10 can be described with reference to the foregoing, and will not be repeated here. The display device 11 disclosed in the embodiment of the present disclosure includes the display panel 10 provided in the above embodiment, so the display device 11 including the display panel 10 also has all the above technical effects, which will not be repeated here.

It should be understood that the terminology used herein is for the purpose of describing specific exemplary embodiments only and is not intended to be limiting. Unless the context clearly indicates otherwise, the singular forms “a”, “an” and “the” as used herein can also mean including plural forms. The terms “include”, “including”, “comprise” and “comprising” are inclusive and thus indicate the presence of features, steps, operations, elements and/or components described, but do not exclude the presence or addition of one or more other features, steps, operations, elements, components, and/or combinations thereof. The method steps, procedures, and operations described herein are not interpreted as necessarily requiring them to be executed in the specific order described, unless the execution order is explicitly indicated. It should also be understood that additional or alternative steps may be used.

Although a plurality of elements, components, regions, layers and/or sections can be described herein with the terms first, second, third, and the like, they should not be limited by these terms. These terms may be only used to distinguish one element, component, region, layer or section from another ones. Terms such as “first” and “second” and other numerical terms do not imply sequence or order when used herein unless clearly indicated in the context. Accordingly, the first element, component, region, layer or section discussed below may be referred to as a second element, component, region, layer or section without departing from teachings of the exemplary embodiments.

The foregoing is only the detailed description of the disclosure to enable a person skilled in the art to understand or implement the disclosure. Various modifications to these embodiments will be apparent to a person skilled in the art, and general principles defined herein can be implemented in other embodiments without departing from the spirit or scope of the disclosure. Thus, the present disclosure is not limited to the embodiments illustrated herein, but conforms to the widest scope consistent with the principle and novel characteristics disclosed herein.

What is claimed is:

1. A display panel comprising a driver chip and a signal line, further comprising:
a line connecting the driver chip and the signal line, comprising a first connecting line and a second connecting line connected to each other; and
a hard substrate and a flexible substrate,
wherein the first connecting line is provided on the hard substrate, the second connecting line is formed on the flexible substrate when the flexible substrate is stretched, and the second connecting line is connected to the first connecting line when the flexible substrate is contracted.

2. The display panel according to claim 1, wherein the second connecting line is connected to an end of the first connecting line.

3. The display panel according to claim 1, wherein the first connecting line comprises a first connecting section and a second connecting section, one end of the second connecting line is connected to one end of the first connecting section, and the other end of the second connecting line is connected to one end of the second connecting section, the other end of the first connecting section is connected to the signal line, and the other end of the second connecting section is connected to the driver chip.

4. The display panel according to claim 1, wherein the first connecting line and the second connecting line are adhesively connected by conductive fluid.

5. The display panel according to claim 1, wherein the flexible substrate can be stretched transversely or longitudinally on a horizontal plane.

6. The display panel according to claim 1, wherein the flexible substrate can be stretched transversely and longitudinally on a horizontal plane.

7. The display panel according to claim 1, wherein a thickness of the second connecting line is smaller than a thickness of the first connecting line when the flexible substrate is stretched; a thickness of the second connecting line is the same as a thickness of the first connecting line when the flexible substrate is contracted.

8. The display panel according to claim 1, wherein the hard substrate is provided with an accommodating groove, and the flexible substrate is embedded in the accommodating groove.

9. The display panel according to claim 8, wherein a depth of the accommodating groove is the same as a thickness of the flexible substrate.

10. The display panel according to claim 8, wherein the flexible substrate comprises a flexible printed surface, the second connecting line is provided on the flexible printed surface, and a thickness direction of the hard substrate is parallel to the flexible printed surface.

11. The display panel according to claim 10, wherein the hard substrate comprises a hard printed surface, the first connecting line is provided on the hard printed surface, the flexible substrate further comprises a first side surface and a second side surface which are both parallel to the hard printed surface and perpendicular to the flexible printed surface, and both ends of the second connecting line are provided on the first side surface.

12. The display panel according to claim 11, wherein the first side surface is provided above the second side surface.

13. The display panel according to claim 10, wherein the hard substrate comprises a hard printed surface, the first connecting line is provided on the hard printed surface, the flexible substrate further comprises a first side surface and a second side surface which are both parallel to the hard printed surface and perpendicular to the flexible printed surface, and two ends of the second connecting line are provided on the first side surface and the second side surface respectively.

14. The display panel according to claim 1, wherein there is a sector area between the signal line and the driver chip, the line is arranged in the sector area, and the sector area includes two outer areas and two inner areas between the two outer areas; a length of the first connecting line in the outer area is greater than a length of the first connecting line in the inner area, and a length of the second connecting line in the outer area is smaller than a length of the second connecting line in the inner area.

15. A display device, comprising a display panel comprising a driver chip and a signal line, the display panel further comprising:
a line connecting the driver chip and the signal line, comprising a first connecting line and a second connecting line connected to each other; and
a hard substrate and a flexible substrate,
wherein the first connecting line is provided on the hard substrate, the second connecting line is formed on the flexible substrate when the flexible substrate is stretched, and the second connecting line is connected to the first connecting line when the flexible substrate is contracted.
